(19) United States
(12) Patent Application Publication
(10) Pub. No.: US 2006/0275928 A1
(43) Pub. Date: Dec. 7, 2006

(54) Semiconductor memory device and operating method for a semiconductor memory device

(76) Inventors: Stefan Wurm, Austin, TX (US); Siegfried Schwarzl, Neubiberg (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 10/512,615

(22) PCT Filed: Mar. 27, 2003
(86) PCT No.: PCT/DE03/01024

§ 371 Date: Jun. 30, 2005

(30) Foreign Application Priority Data
Apr. 26, 2002 (DE) 102-18-785.1

(51) Int. Cl. H01L 21/00; H01L 29/94

(52) U.S. Cl. 438/3; 257/295

(57) ABSTRACT

A magnetoresistive semiconductor memory device is proposed, in which a magnetic field can be applied to memory cells by means of a magnetic field applying device such that a desired magnetization can be impressed on hard-magnetic layers of the memory cells acted on.

### BACKGROUND

The invention relates to a semiconductor memory device and to a method for operating a semiconductor memory device.

In semiconductor memory devices based on a magnetoresistive storage mechanism, in particular in MRAM memories, what is crucially important is a prescribed and fixed premagnetization of specific regions of the memory cells in comparison with freely magnetizable regions of the respective memory cells. In this case, a tunneling resistance which forms between two magnetized layers and is used to measure an electric current for sensing the memory content of a respective cell depends very greatly on the strength and the orientation of the fixedly prescribed premagnetization and also on the freely adjustable magnetization.

Although there are known materials in the construction of memory cells based on magnetoresistive storage effects in which a fixedly preset premagnetization hardly changes with respect to time, it cannot be ensured that a memory area will exhibit 100% freedom from faults over the period of utilization of a number of years on account of the high number of individual memory cells in a memory area for semiconductor memory devices based on magnetoresistive storage mechanisms.

Thus, it is conceivable, for example, that due to external interference fields, due to thermal influences and/or also spontaneously, specific premagnetized regions of the memory cells will exhibit deviations from a desired magnetization with regard to the strength and/or the orientation of the premagnetization, with the result that individual memory cells or memory elements of a memory area may become unusable. A term that is also used in this connection is so-called magnetic creeping, in which a misorientation of the premagnetization or else a decrease in the strength of the premagnetization is a temporally crawling process, in which case a malfunction of the respective memory cell can then suddenly occur.

### SUMMARY

One embodiment of the invention specifies a semiconductor memory device based on a magnetoresistive storage mechanism and also a method for operating a semiconductor memory device based on a magnetoresistive storage mechanism, in the case of which a memory operation that is as reliable as possible can be realized over a long operating period.

One embodiment of the invention is a semiconductor memory device based on a magnetoresistive storage mechanism, and in particular the MRAM memory, have at least one memory area, which, for its part, has a plurality of memory cells. Furthermore, at least one magnetic field applying device is provided, by means of which a common and at least locally homogeneous magnetic field can be applied to at least some of the memory cells in a controllable and/or defined fashion such that, as a result, at least parts or regions of the memory cells acted on can be amplified and/or oriented in defined and/or controllable fashion with regard to their magnetization (magnetic polarization).

In one case of a magnetoresistive semiconductor memory device in accordance with the present invention, a magnetic field applying device is formed by means of which, during operation, a magnetic field can be applied to the memory cells controllably in a defined manner in order thereby to amplify and/or orient the magnetic polarization and/or the magnetization of the individual cells in a defined manner and controllably. Thus, during operation, magnetic creeping can be counteracted by virtue of the fact that, for the respective component parts of the memory cells which are to be formed with a fixed premagnetization, this premagnetization is formed and/or amplified in a well-defined manner. As a result, a misorientation of the premagnetization of the respective memory cells is counteracted and it is thus possible to speak in this case of a reorientation or amplification of the premagnetization.

In one embodiment of the semiconductor memory device according to the invention, it is provided that the magnetic field applying device is formed entirely or partially in a housing device provided for the semiconductor memory device. In this case, the specific housing component parts of the housing device or else the housing device as a whole can be formed as a prefabricated element with the magnetic field applying device, without having to modify the production and test procedure for the semiconductor memory device in the narrower sense, that is to say of the semiconductor module underlying the semiconductor memory device. Consequently, the semiconductor memory underlying the semiconductor memory device can be formed and tested independently of the magnetic field applying device to be provided.

In another embodiment of the semiconductor memory device according to the invention, it is provided that the magnetic field applying device is formed as a coil arrangement. The latter may have one coil or a plurality of coils.

In this case, the coil arrangement is arranged and/or formed in such a way that a magnetic field of the inner region of at least one coil can be applied to at least some of the memory cells. On account of the geometry of coils, it is precisely the inner regions that have particularly high magnetic field strengths during operation, a particularly suitable homogeneity of the magnetic field generated also being ensured.

In order to realize the procedure, it is provided that at least one coil of the coil arrangement spatially encloses at least some of the memory cells.

This may mean, for example, that the semiconductor module underlying the semiconductor memory device is formed and/or arranged at least partly in the inner region of at least one coil of the coil arrangement.

Certain spatial regions in coils of coil arrangements can generate, in the outer region, suitable magnetic field strengths with a suitable orientation.

Therefore, in accordance with another embodiment of the semiconductor memory device according to the invention, it is provided that a magnetic field of the outer region of at least one coil can be applied to at least some of the memory cells.

To that end, it is provided that at least part of the semiconductor module underlying the semiconductor memory device is arranged and/or formed in the outer region of at least one coil.

The semiconductor memory device according to an embodiment of the invention have favorable properties with regard to a reorientation and/or amplification to be carried out for the premagnetization provided result if two coils are provided as elements of the coil arrangement of the magnetic field applying device.

If a plurality of coils, either two or more, are provided in the formation of the coil arrangement of the magnetic field applying device, then said coils are formed in identically acting or identical fashion.

Particularly simple field conditions result if, in accordance with an alternative embodiment of the semiconductor memory device according to the invention, the plurality of coils, in particular two coils, of the coil arrangement of the magnetic field applying device are formed in axially symmetrical fashion with respective axes of symmetry and if, in this case, the two or more coils additionally run with their axes of symmetry on a common axis and/or are arranged collinearly with respect to one another.

In this case, it is furthermore advantageous if the two coils are arranged and/or formed along their common axes or axis of symmetry in a manner spaced apart spatially from one another with an intermediate region, in which case the semiconductor module underlying the semiconductor memory device is then arranged and/or formed at least partly in said intermediate region between the coils, in particular in the vicinity of the common axis or axis of symmetry of the coils. This procedure is advantageous insofar as the geometrical arrangement of the coils thus formed enables, during operation, a particularly high field strength and, at the same time, a particularly high homogeneity in the intermediate region between the coils that are operated serially with respect to one another.

The memory cells each have or form a magnetoresistive memory element, in particular a TMR stack element with at least one hard-magnetic layer.

Furthermore, it is provided that the memory cells each have at least one soft-magnetic layer as memory layer and also a tunnel layer arranged between the hard-magnetic layer and the soft-magnetic layer.

Furthermore, in one embodiment it is advantageous that the hard-magnetic layer is in each case formed with a predefined and fixed magnetization as desired magnetization, said desired magnetization being oriented, in particular, in each case perpendicularly to a course direction of the TMR stack elements, that is to say the direction of the course of the sequence of layers of the TMR stack elements, for example in the plane of the layers.

The semiconductor memory device according to one embodiment of the invention is configured in a particularly simple manner if the plurality of memory cells is formed essentially in identically acting or identical fashion.

Furthermore, in one embodiment it is advantageous that the plurality of memory cells is arranged and/or formed in such a way that their magnetizations are oriented essentially identically and/or lie essentially in a common plane.

One embodiment of the present invention provides a method for operating a semiconductor memory device based on a magnetoresistive storage mechanism, and in particular for an MRAM memory. The operating method according to this embodiment of the invention has a step of read-out and external storage of memory contents of each memory cell of a memory area of the semiconductor memory device. Afterward, a magnetic field is then applied to the semiconductor memory device and, in the process, a magnetic field is applied to at least some of the memory cells in order to impress a magnetization on hard-magnetic layers of the memory cells in a definable and/or controllable fashion. Afterward, the externally stored memory contents are then written back to each cell of the memory area.

Thus, this embodiment of the method firstly saves the data contents of the memory area in order subsequently to amplify and/or reorient the hard-magnetic layers of the memory cells by impressing a magnetization in a definable and/or controllable manner. Afterward, the information state of the memory area is then re-established by writing back the externally stored or saved memory contents to respective memory cells.

The operating method according to one embodiment of the invention is configured in a particularly advantageous manner if the magnetic field is set in a controlled fashion in terms of strength, orientation and time duration in such a way that each of the memory cells to be acted on has impressed on it a magnetization in a defined fashion in terms of strength and orientation so that a reliable memory operation is ensured, and/or that, in particular, the respective magnetization of hard-magnetic layers of the memory cells can be reoriented toward the desired magnetization and/or amplified.

Furthermore, in one embodiment the steps—underlying the operating method—of externally saving the memory contents, of applying a magnetic field for reorientation and/or for amplification of the magnetization, and of writing back the externally saved memory contents are carried out repeatedly at time intervals, in particular at a time interval of one year or less. This repetition can be effected regularly.

A regularity in the execution of the operating method thus ensures a preventive measure. On the other hand, the execution of the method can also be carried out by an explicit request by a user or by a using unit, for example for the case where an error state is ascertained with regard to the storage or read-out of information contents.

The tunneling magnetoresistance memory elements, TMR, also called magnetic tunneling junctions MTJ, of magnetic random access memories (MRAMs) have a passive and an active ferromagnetic layer. The magnetization of the active layer is rotated during writing and destructive reading relative to the fixed direction of magnetization of the passive magnetic layer, parallel or antiparallel to said direction of magnetization.

The nonvolatility of this type of memory is essentially concomitantly determined by the orientation of the magnetization of the passive hard-magnetic layer, said orientation not changing with respect to time. The orientation of this magnetization is defined once during the production process. The deviation that can be tolerated in this case is low, less than one degree. This narrow distribution of the magnetization around a predetermined direction can become wider over the course of time with and without external magnetic interference fields, for example due to magnetic creeping. The changes in magnetization must be expected to take place inhomogeneously, proceeding from nucleation centers. As a result, individual memory elements may become unusable, and/or their memory contents may be lost.

The time scale to which the nonvolatility of MRAM memories based on the tunneling magnetoresistance effect (TMR) relates is not known. It must be expected, however, that, due to thermal activation of the magnetic creeping in the hard-magnetic layer, this time scale will fall within the range of the period of utilization of the memories of a few years.

It is not known how the limitation of the nonvolatility caused by magnetic creeping can be prevented.

Changes in magnetization due to external magnetic interference fields and the loss of stored information thus caused can be prevented by magnetic shielding with materials of high permeability.

These are ineffective, however, with regard to the information losses caused by magnetic creeping.

The hard-magnetic layer can be reoriented by an external magnetic field, even during the operation of an MRAM module. Therefore, one embodiment of the invention provides for the repair or the preventive refreshing of memory cells which have lost their functionality due to a change in the magnetization of the hard-magnetic layer.

For this purpose, firstly the content of the memory module is buffer-stored in another arbitrary medium. A magnetic field large enough to reorient the hard-magnetic layer is then applied, for example by means of a coil suitably integrated in the package, or a pair of coils. Afterward, the former content can be transferred back into the module from the buffer memory. This operation can be repeated as often as desired.

If, as proposed, a coil or a pair of coils is integrated into the package of the module, then the orientation of the magnetization of the hard-magnetic layer of the module can be refreshed in situ. A corresponding logic with driving can carry out this operation automatically at predetermined time intervals. The time scale thus changes for the definition or requirements with regard to nonvolatility made of the hard-magnetic layer. It is possible to realize long-term nonvolatile memories even with hard-magnetic layers whose magnetic orientation decomposes over a shorter time scale.

Hard-magnetic layers can be obtained through special alloys of ferromagnetic and nonferromagnetic elements, for example CoFe, CoCr, CoPt, CoCrFe.

However, the magnetic switching thresholds of ferromagnetic layers can also be increased through the choice of layer geometry (shape, thickness) in comparison with the soft-magnetic layers.

A further possibility consists in making ferromagnetic layers “harder” by coupling to underlying, alternatively overlying, antiferromagnetic layers (for example made of IrMn, PtMn).

Appropriate ferromagnetic layers are generally layers which contain at least one of the elements Fe, Ni, Co, Cr, Mn, Gd, Dy or Bi or comprise alloys thereof.

One embodiment of the invention includes exploiting the insight that, in contrast to other nonvolatile memories, such as flash memories, for example, defective cells or bits can be refreshed or repaired by an applied external field.

The magnetic field of the hard-magnetic layer can be refreshed or repaired contactlessly by exposing the chip in the package to an oriented magnetic field.

If a corresponding coil or a pair of coils is integrated into the package, for example a housing, then memory cells whose defect is attributable to a misorientation of the magnetization in the hard-magnetic layer can be repaired in situ in the course of operation, for example during times in which the corresponding memory cells are not accessed.

If this reorientation is carried out as a preventive measure, then the nonvolatility of these memory elements can be improved.

The magnetic field for re-establishing the direction of magnetization of the hard-magnetic layer is generated for example by a pair of coils mounted together with the MRAM chip in a chip housing. The magnetic fields of the two series-connected coils are unidirectional and focused onto the chip plane.

It is also possible to use an elongate magnetic coil mounted above the chip in a housing. For reorientation of the hard-magnetic layer, the external magnetic field which is approximately parallel to the coil axis is used, for example, which magnetic field, together with the magnetic field within the coil, forms a closed magnetic field arrangement. Compared with the above procedure, the simplicity of the mounting is advantageous, but the lower magnetic-field-to-current efficiency is disadvantageous.

The following further exemplary embodiments are conceivable:
the magnetic coil encloses the MRAM chip in closely adjoining fashion and comprises one or more coil segments. In this case, the homogeneous magnetic field is advantageous; the magnetic field is at a maximum for a given current. The complicated mounting is disadvantageous.
the magnetic coil is integrated into the constituent parts of the housing in such a way that a complete magnetic coil enclosing the MRAM chip is produced after the mounting of the MRAM chip and assembly of the constituent parts of the housing. The simple mounting and the high magnetic-field-to-current efficiency are advantageous in this case. The expensive, complex housing is disadvantageous.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description.

The elements of the drawings are not necessarily to scale relative to each other.

Like reference numerals designate corresponding similar parts.

FIGS. 1A-D diagrammatically illustrate four different intermediate states of a memory cell which are attained in accordance with one embodiment of the operating method according to the invention.

FIGS. 2A-C illustrate three different embodiments of the semiconductor memory device according to the invention in sectional side view.

FIG. 3 illustrates another embodiment of the semiconductor memory device according to the invention in partial sectional and perspective side view.

FIG. 4 illustrates a further embodiment of the semiconductor memory device according to the invention in partially sectional side view.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

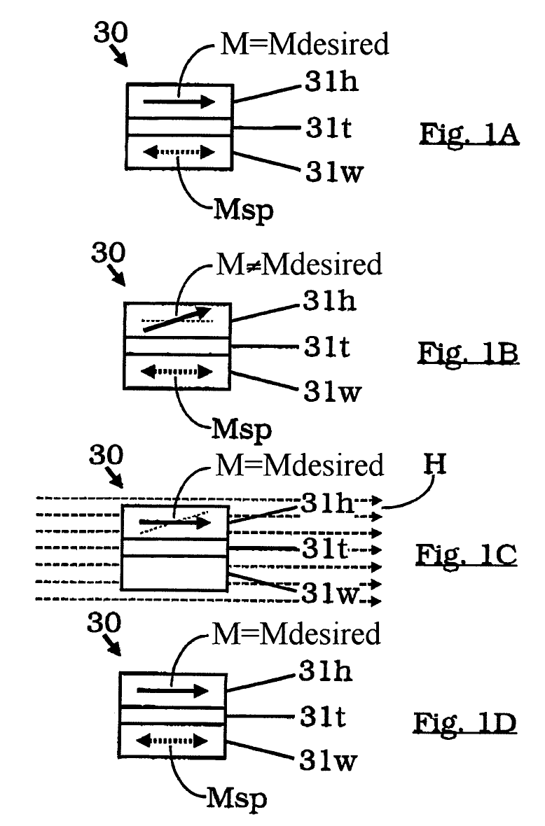

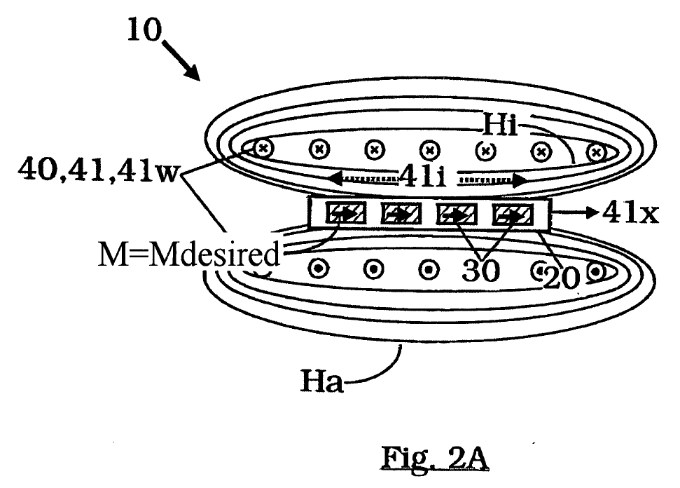

The procedure in accordance with one embodiment of the operating method according to the invention is explained in detail on the basis of a single memory cell 30 based on a magnetoresistive storage mechanism with reference to FIGS. 1A to 1D in sectional side view.

In the embodiment of the invention illustrated in FIGS. 1A to 1D, a magnetoresistive memory cell 30 comprises a hard-magnetic layer 31h, a soft-magnetic layer 31w and a tunnel layer 31t provided in between. During the fabrication of a semiconductor memory device according to one embodiment of the invention, which has a plurality of the memory cells 30 illustrated in FIGS. 1A to 1D in a memory area 20, a magnetization M is impressed on the hard-magnetic layer 31h of each memory cell 30, which magnetization is essentially identical to a desired magnetization Mdesired:M=Mdesired, to be precise in terms of magnitude and direction.

By means of corresponding write operations, an information magnetization or storage magnetization Msp can be impressed on the soft- magnetic layer 31w, which serves as memory layer, parallel or antiparallel to the desired magnetization Mdesired of the, hard-magnetic layer 31h. A comparatively high or a comparatively low electrical tunneling resistance via the tunnel layer 31t of the memory cell 30 is established depending on whether the storage magnetization Msp of the soft-magnetic layer 31w is oriented parallel or antiparallel to the desired magnetization Mdesired of the hard-magnetic layer 31h.

This state is illustrated in FIG. 1A and is present at an instant t=0 and for some time afterwards, the storage magnetization Msp of the soft-magnetic layer 31w being indicated in dotted fashion on account of its variability.

As time passes, the probability of the magnetization M of the hard-magnetic layer 31h deviating from the desired magnetization Mdesired increases. This applies both with regard to the absolute magnitude of the magnetization M and with regard to the direction of the magnetization M in comparison with the desired magnetization Mdesired. FIG. 1B diagrammatically illustrates that, for a time t above a critical time Tcrit, not specified in any further detail, there is a deviation of the magnetization M of the hard-magnetic layer 31h in terms of magnitude and direction in comparison with the desired magnetization Mdesired:M≠Mdesired.

In the text above and below, M, Msp, Mdesired always represent fixed-amount quantities or quantities that are averaged over the corresponding layers.

Such a deviation can have the effect that the functional reliability is no longer ensured when writing and/or reading information contents to and/or from the soft-magnetic layer 31w of the memory cell 30.

Accordingly, an external magnetic field H with respect to the memory element 30 (or the memory cell 30) is applied in accordance with the illustration of FIG. 1C. This external magnetic field H is chosen with regard to its direction and its magnitude such that the magnetization M of the hard-magnetic layer 31h is again oriented in accordance with the desired magnetization Mdesired and, in its magnitude, assumes a corresponding or higher value, as is illustrated in FIG. 1C.

After the external magnetic field H with respect to the memory cell 30 has been switched off, an amplified and reoriented magnetization M corresponding to the desired magnetization Mdesired:M=Mdesired remains in the hard-magnetic layer 31h.

This is illustrated in FIG. 1D, in which case, in the transition from the state of FIG. 1B to FIG. 1C, the information stored in the soft-magnetic layer 31w is read from the memory cell 30 and is subsequently written back to the soft-magnetic layer 31w in the transition from the state of FIG. 1C to the state of FIG. 1D, so that the storage magnetizations Msp of the states of FIGS. 1B and 1D essentially correspond.

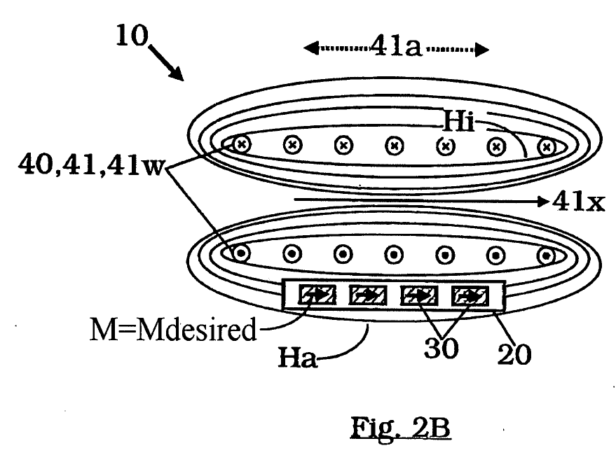

FIGS. 2A to 2C illustrate three embodiments of the semiconductor memory device 10 according to the invention in diagrammatic and sectional side view.

In FIGS. 2A to 2C, the semiconductor memory device 10 according to one embodiment of the invention has a memory area 20 which, for its part, has a plurality of memory elements or memory cells 30 which, for their part, have the structure illustrated in FIGS. 1A to 1D, for example. The memory area 20 in each case has the structure of a semiconductor module 20 or of a chip 20.

The magnetic field applying devices 40 of the embodiments of FIGS. 2A to 2C are formed by coil arrangements 40. In this case, one coil 41 is provided in each of the embodiments of FIGS. 2A and 2B and two coils 41 and 42 are provided in the embodiment of FIG. 2C. In each case only the cross sections of the turns 41w and 42w, respectively, of the coils 41, 42 are indicated.

In the embodiments of FIGS. 2A to 2C, all the coils have a cylindrical or parallelepipedal configuration with in each case a centrally arranged axis 41x and 42x of symmetry.

In the embodiment of FIG. 2A, the memory chip or memory area 20 with its memory cells 30 is arranged in the inner region 41i of the coil 41 of the coil arrangement or magnetic field applying device 40 and has applied to it there during operation a homogeneous magnetic field Hi, which, in terms of direction and magnitude, generates precisely the desired magnetization Mdesired in the hard-magnetic layers 31h of the memory cells 30.

In the embodiment of FIG. 2B, the memory area 20 with its memory cells 30 is provided in the outer region 41a of the coil 41 of the coil arrangement 40 or magnetic field applying device 40, so that the outer field Ha of the coil 41 is exclusively used there for the application and reorientation.

In the embodiment of FIG. 2C, the memory area 20 with its memory cells 30 is situated in the intermediate region Z of the first coil 41 and the second coil 42, which are of identical design and have axes 41x and 42x of symmetry, said axes 41x and 42x of symmetry lying and being oriented on a common axis X of symmetry. Consequently, in the embodiment of FIG. 2C, the combined emergence field Ha of the first coil 41 and second coil 42 is used as superposed magnetic field for the reorientation of the magnetization M of the hard-magnetic layers 31h.

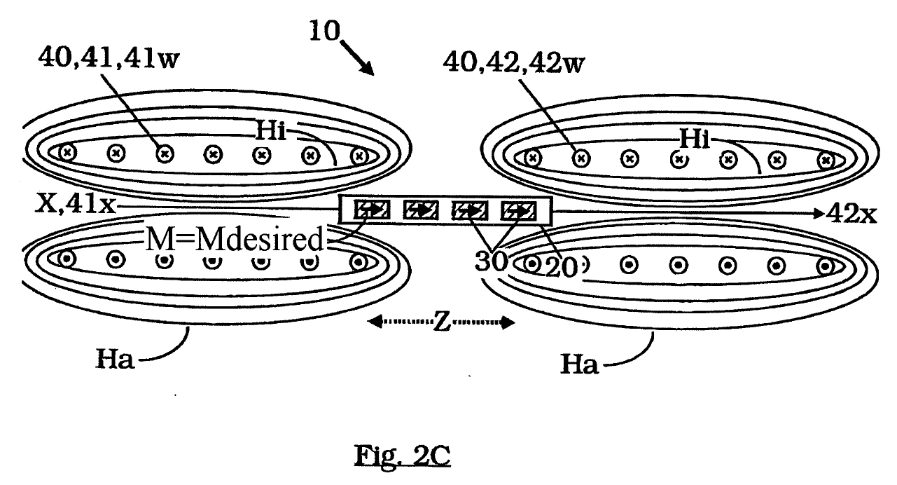

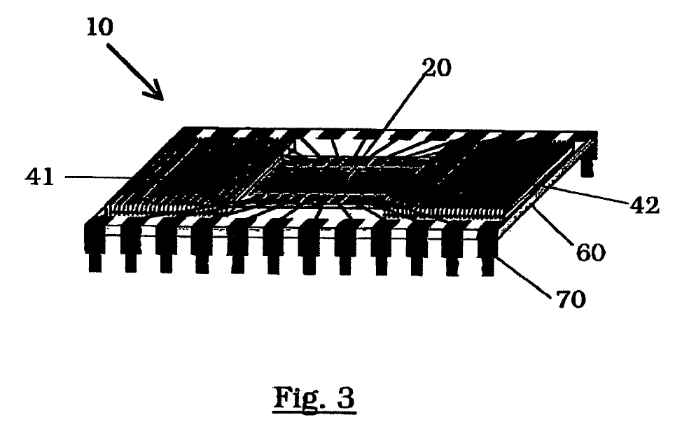

FIG. 3 illustrates, in diagrammatic, partially perspective sectional side view, a more highly concretized embodiment of a semiconductor memory device 10 according to the invention using the arrangement illustrated in FIG. 2C. First and second coils 41, 42 are provided there, too. Said coils are constructed essentially identically and have axes 41x, 42x of symmetry arranged collinearly on a line. The first and second coils 41, 42 are spaced apart spatially from one another by an intermediate region Z. Located in the intermediate region Z is the chip as memory area 20 with the memory cells 30 provided therein. The illustration also shows a carrier substrate 60 and external terminals 70. The first and second coils 41 and 42 are provided here as structures that are integrated into a housing that is not concretized in any further detail here.

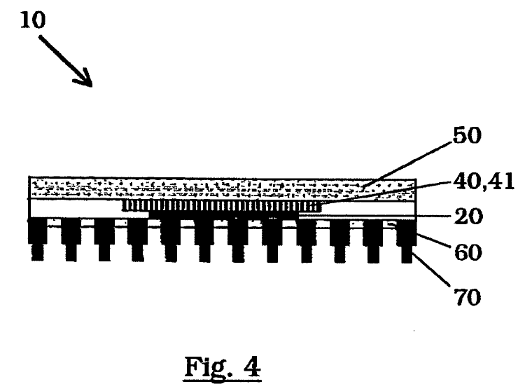

FIG. 4 illustrates a more highly concretized embodiment of the arrangement of FIG. 2B in sectional side view. A magnetic field applying device 40 with a coil arrangement 40 comprising a single coil 41 is provided there in the housing region 50. The memory area 20 formed as a chip is situated in the outer region 41a of the individual coil 41. The chip or memory area 20 and all further components lie on a carrier substrate 60 and are contact-connected externally by external terminals 70.

What is claimed is:

1-20. (canceled)

21. A semiconductor memory device based on a magnetoresistive storage mechanism, comprising:
at least one memory area having a plurality of memory cells; and
at least one magnetic field applying device, by means of which a common and at least locally homogeneous magnetic field can be applied to at least some of the memory cells in a controllable fashion;
wherein at least regions of the memory cells acted on by the magnetic field applying device can be amplified and oriented in a controllable fashion with regard to their magnetization.

22. The semiconductor memory device of claim 21, wherein the magnetic field applying device is formed at least partially in a housing device provided for the semiconductor memory device.

23. The semiconductor memory device of claim 21, wherein the magnetic field applying device is formed as a coil arrangement, having at least one coil.

24. The semiconductor memory device of claim 23, wherein the coil arrangement is arranged such that a magnetic field of an inner region of at least one coil can be applied to at least some of the memory cells.

25. The semiconductor memory device of claim 23, wherein at least one coil spatially encloses at least some of the memory cells.

26. The semiconductor memory device of claim 24, wherein a semiconductor module underlying the semiconductor memory device is formed at least partly in the inner region of at least one coil.

27. The semiconductor memory device of claim 26, wherein a magnetic field of an outer region of at least one coil can be applied to at least some of the memory cells.

28. The semiconductor memory device of claim 27, wherein at least part of the semiconductor module underlying the semiconductor memory device is arranged in the outer region of at least one coil.

29. The semiconductor memory device of claims 23, wherein two coils are provided.

30. The semiconductor memory device of claims 23, further including a plurality of coils that are formed essentially in identical fashion.

31. The semiconductor memory device of claim 23, further including two axially symmetrical coils with axes of symmetry and wherein the two coils are arranged with their axes of symmetry running on a common axis.

32. The semiconductor memory device of claim 31, wherein the two coils are arranged along their common axis in a manner spaced apart spatially with an intermediate region, and wherein a semiconductor module underlying the semiconductor memory device is arranged at least partly in the intermediate region between the coils in particular in the vicinity of the common axis.

33. The semiconductor memory device of claim 21, wherein the memory cells each have a magnetoresistive memory element, in particular a TMR stack element with at least one hard-magnetic layer.

34. The semiconductor memory device of claim 33, wherein the memory cells each have at least one soft-magnetic layer as memory layer and also a tunnel layer arranged between the hard-magnetic layer and the soft-magnetic layer.

35. The semiconductor memory device of claims 34, wherein the hard-magnetic layer is in each case formed with a predefined magnetization as desired magnetization, which is in each case oriented perpendicularly to a course direction of the TMR stacked element or elements.

36. The semiconductor memory device of claim 21, wherein the plurality of memory cells is formed essentially in identical fashion.

37. The semiconductor memory device of claim 21, wherein the plurality of memory cells is arranged or formed in such a way that their magnetizations are oriented to lie essentially in one plane.

38. A method for operating a semiconductor memory device based on a magnetoresistive storage mechanism comprising:
reading and externally storing memory contents of each memory cell of a memory area of the semiconductor memory device;
applying a magnetic field to the semiconductor memory device and applying the magnetic field to at least some of the memory cells in order to impress a magnetization on hard-magnetic layers of the memory cells in a definable and controllable fashion; and
writing-back the externally stored memory contents to the respective cells of the memory area.

39. The method of claim 38, wherein the magnetic field is set in a controlled fashion in terms of its strength, orientation and time duration in such a way that each memory cell to be acted on has impressed on it a magnetization in a defined fashion in terms of strength and orientation such that a reliable memory operation is ensured, and that, in particular, the respective magnetization of hard-magnetic layers of the memory cells is reoriented toward the desired magnetization (Mdesired) and amplified.

40. The method of claim 38, wherein steps reading memory contents, applying a magnetic field and writing-back memory contents are carried out in a manner repeated at regular time intervals, and in particular at a time interval of one year or less and upon explicit request by a user.

41. A magnetoresistive semiconductor memory device comprising:
a memory area having a plurality of memory cells; and
means for applying a locally homogeneous magnetic field to at least some of the memory cells in a controllable manner such that at least regions of the memory cells can be oriented in a controllable manner with respect to their magnetization.

42. The magnetoresistive semiconductor memory device of claim 41, wherein the magnetic field is impressed upon hard magnetic layers of the memory cells.
